(19) United States
(12) Patent Application Publication
(10) Pub. No.: US 2023/0422476 A1
(43) Pub. Date: Dec. 28, 2023

(54) SEMICONDUCTOR DEVICE

(71) Applicant: SK hynix Inc., Gyeonggi-do (KR)

(72) Inventor: Jun Sik KIM, Gyeonggi-do (KR)

(21) Appl. No.: 17/987,958

(22) Filed: Nov. 16, 2022

(30) Foreign Application Priority Data
Jun. 27, 2022 (KR) 10-2022-0078017

(51) Int. Cl. H01L 27/108

(52) U.S. Cl. CPC H01L 27/10805

(57) ABSTRACT

A semiconductor device includes: a vertical conductive line oriented vertically in a first direction; a horizontal layer oriented horizontally in a second direction from the vertical conductive line; and a horizontal conductive line oriented horizontally in a third direction intersecting with the horizontal layer, wherein the horizontal conductive line includes: a high work function electrode including a material having a higher work function than titanium nitride; and a low work function electrode including a semiconductor material.

### CROSS-REFERENCE TO RELATED APPLICATIONS

The present application claims priority of Korean Patent Application No, 10-2022-0078017 filed on Jun. 27, 2022, which is incorporated herein by reference in its entirety.

### BACKGROUND

### 1. Field

Various embodiments of the present invention relate to a semiconductor device, and more particularly, to a semiconductor device including memory cells, and a method for fabricating the same.

### 2. Description of the Related Art

Recently, in order to cope with the increase in capacity and miniaturization of memory devices, a technology for providing a three-dimensional (3D) memory device including a plurality of memory cells that are stacked is suggested.

### SUMMARY

Various embodiments of the present invention are directed to a semiconductor device including memory cells that are capable of realizing high integration and high operating speed, and a method for fabricating the semiconductor device.

In accordance with an embodiment of the present invention, a semiconductor device includes: a vertical conductive line oriented vertically in a first direction; a horizontal layer oriented horizontally in a second direction from the vertical conductive line; and a horizontal conductive line oriented horizontally in a third direction intersecting with the horizontal layer, wherein the horizontal conductive line includes: a high work function electrode including a material having a higher work function than titanium nitride; and a low work function electrode including a semiconductor material.

In accordance with another embodiment of the present invention, a semiconductor device includes: a vertical conductive line oriented vertically in a first direction; a horizontal layer oriented horizontally in a second direction from the vertical conductive line; and a horizontal conductive line oriented horizontally in a third direction intersecting with the horizontal layer, wherein the horizontal conductive line includes: a high work function electrode including a molybdenum-based material; a first low work function electrode disposed on a first side of the high work function electrode; and a second low work function electrode disposed on a second side of the high work function electrode.

In accordance with yet another embodiment of the present invention, a semiconductor device includes: a first doped region; a second doped region; a channel between the first doped region and the second doped region; a high work function electrode overlapping with the channel; a first low work function electrode overlapping with the first doped region; and a second low work function electrode overlapping with the second doped region, wherein the high work function electrode includes a stack of molybdenum nitride and molybdenum, and the first and second low work function electrodes may include doped polysilicon.

These and other features and advantages of the present invention will become understood by the skilled person from the detailed description in conjunction with the following drawings.

### BRIEF DESCRIPTION OF THE DRAWINGS

FIG. 1 is a simplified schematic plan view illustrating a semiconductor device in accordance with an embodiment of the present invention.

FIG. 2A is a simplified schematic perspective view illustrating a memory cell shown in FIG. 1,

FIG. 2B is a simplified schematic cross-sectional view illustrating the memory cell shown in FIG. 2A.

FIG. 3A is a simplified schematic cross-sectional view taken along a line A-A′ of FIG. 1.

FIG. 3B is a simplified schematic cross-sectional view taken along a line a B-B′ of FIG. 1.

FIGS. 4A to 4E are detailed views illustrating diverse embodiments of a horizontal conductive line.

FIG. 5 is a simplified schematic cross-sectional view illustrating a semiconductor device in accordance with another embodiment of the present invention,

FIG. 6 is a simplified schematic cross-sectional view illustrating a semiconductor device in accordance with another embodiment of the present invention.

### DETAILED DESCRIPTION

Various embodiments of the present invention Will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

A cell threshold voltage (CVT) depends on a flat-band voltage. The flat band voltage depends on a work function. The work function may be engineered by diverse methods. For example, the work function may be adjusted by a material of a gate electrode (or a word line), a material between the gate electrode and a channel, a dipole, and the like. The flat band voltage may be shifted by increasing or decreasing the work function. A high work function may shift the flat band voltage in a positive direction, and a low work function may shift the flat band voltage in a negative direction. As described above, the cell threshold voltage may be adjusted by shifting the flat band voltage.

The following embodiments of the present invention relate to a three-dimensional Dynamic Random Access Memory (DRAM), wherein a word line may include a low work function electrode and a high work function electrode. The low work function electrode may be adjacent to a capacitor, and the high work function electrode may be adjacent to a bit line. The low work function electrode may include polysilicon, and the high work function electrode may include a metal-based material.

Due to the low work function of the low work function electrode, a low electric field is formed between a horizontal line and the capacitor, thereby improving the problem of leakage current.

The high work function of the high work function electrode may not only adjust a threshold voltage but also lower the height of a memory cell by forming a low electric field, which is advantageous in terms of integration.

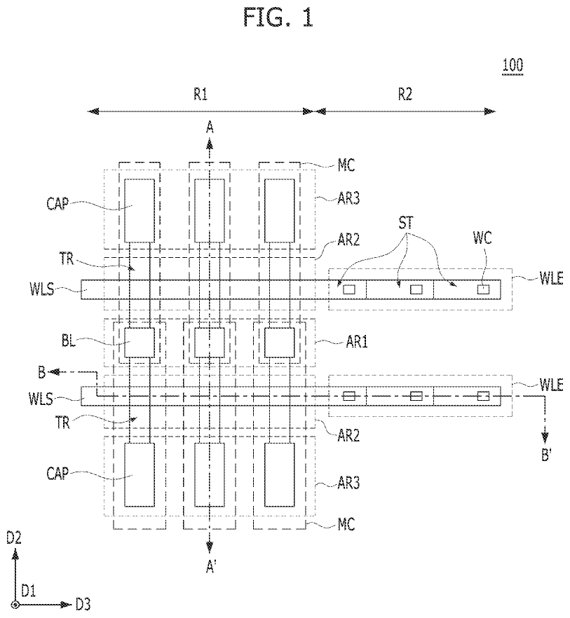

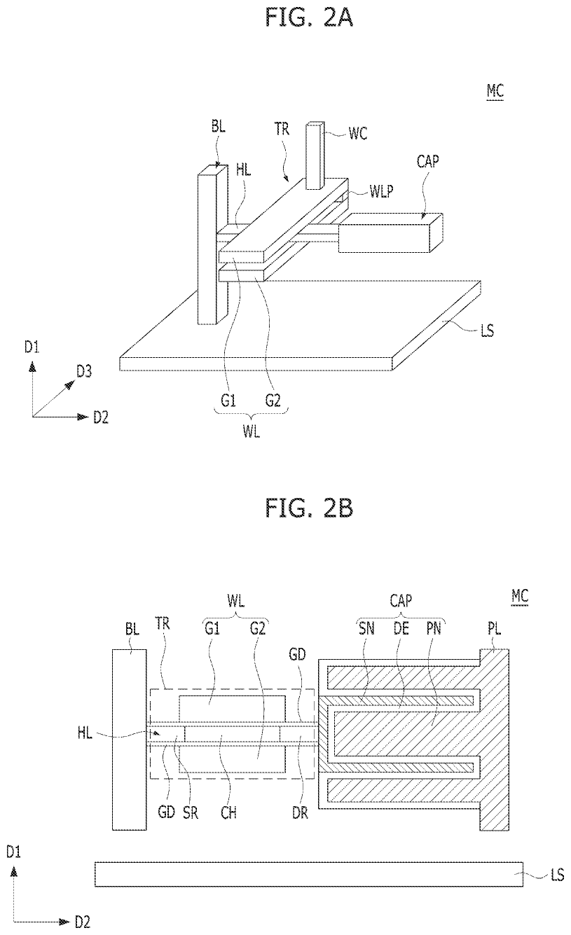

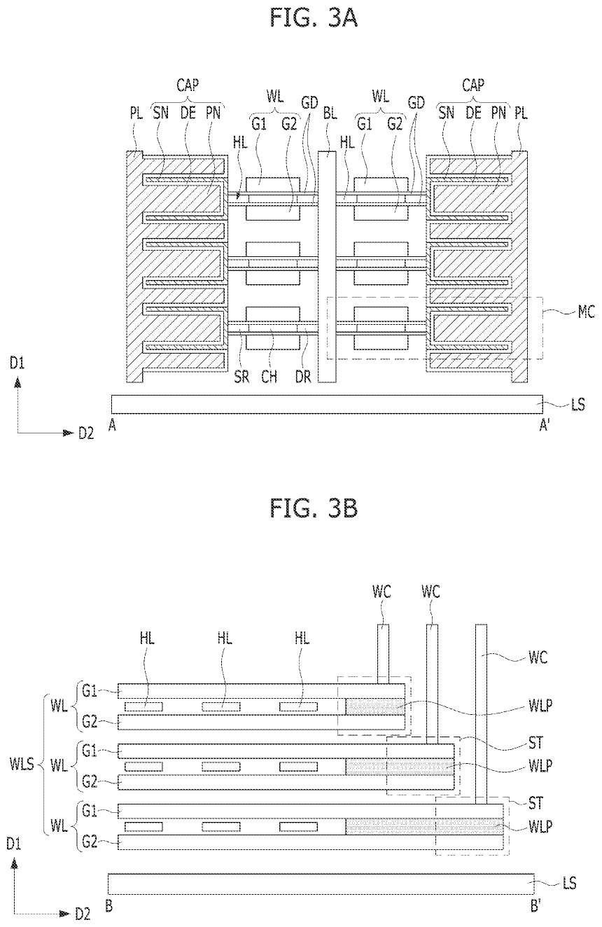

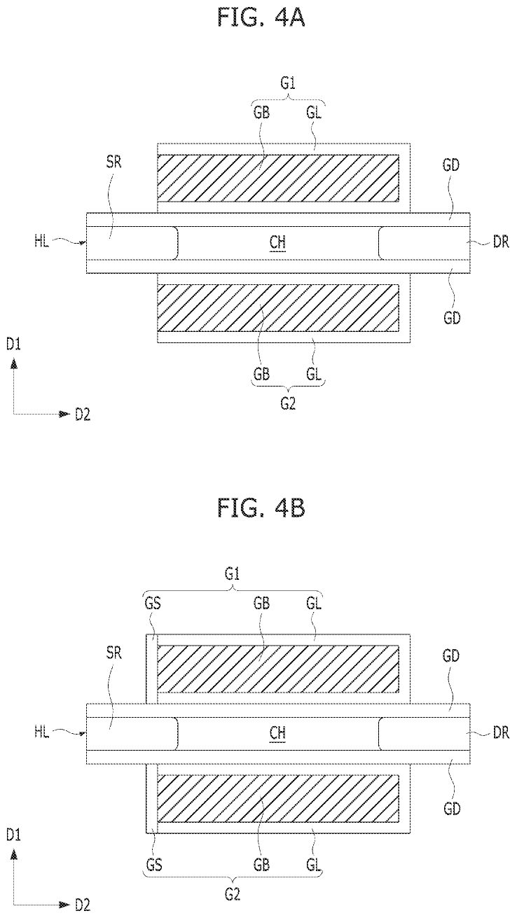

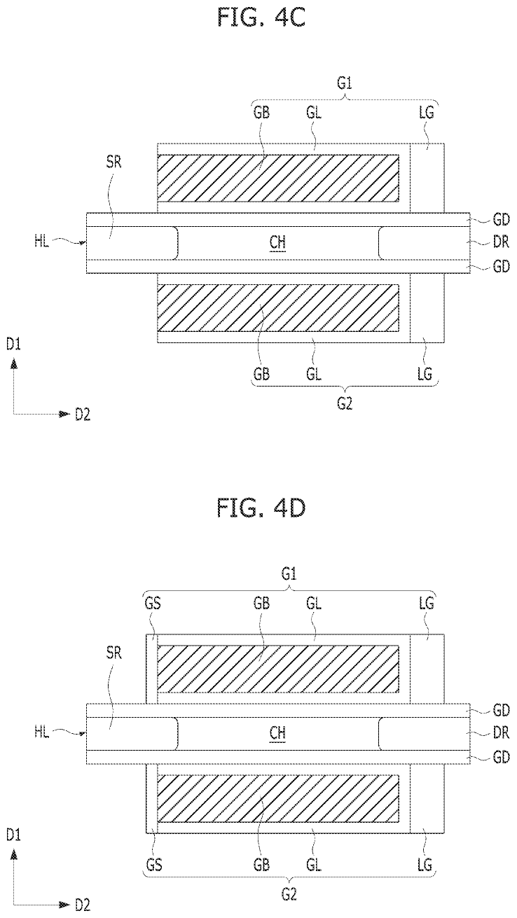

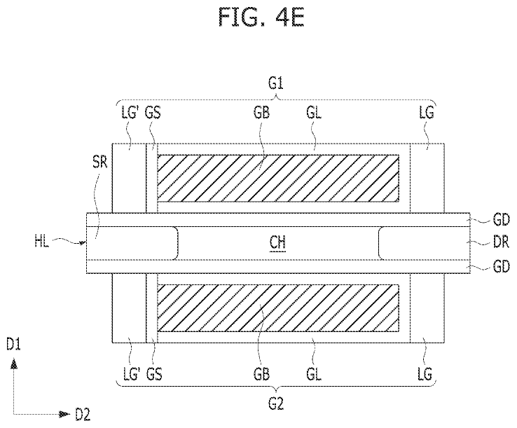

FIG. 1 is a simplified schematic plan view illustrating a semiconductor device in accordance with an embodiment of the present invention. FIG. 2A is a simplified schematic perspective view illustrating a memory cell shown in FIG. 1. FIG. 2B is a simplified schematic cross-sectional view illustrating the memory cell shown in FIG. 2A, FIG. 3A is a simplified schematic cross-sectional view taken along a line A-A′ of FIG. 1. FIG. 3B is a simplified schematic cross-sectional view taken along a line a B-B′ of FIG. 1. FIGS. 4A to 4E are detailed views illustrating diverse embodiments of a horizontal conductive line.

Referring to FIGS. 1 to 4E, the semiconductor device 100 may include a first array AR1, a second array AR2, and a third array AR3. The first array AR1 may include an array of vertical conductive lines BL. The second array AR2 may include an array of switching elements TR. The third array AR3 may include an array of data storage elements CAP. The semiconductor device 100 may further include stack structures WLS. The stack structures WLS may include horizontal conductive lines WL that are stacked in a first direction D1. The vertical conductive lines BL may be vertically oriented in the first direction D1. The first array AR1, the second array AR2, and the third array AR3 may be disposed horizontally in a second direction D2. The stack structures WLS may be oriented horizontally in a third direction D3.

The semiconductor device 100 may include an array of a plurality of memory cells MC. Each memory cell MC may include a vertical conductive line BL, a switching element TR, and a data storage element CAP. The switching element TR may include a stack structure WLS, Memory cells MC at the same level that are disposed adjacent to each other in the second direction D2 may share one vertical conductive line BL. The memory cells MC may be disposed at a higher level than a lower structure LS. Referring back to FIG. 2B, the array of the memory cells MC has a mirror-type structure that shares one vertical conductive line BL. For example, as shown in FIG. 3A, six memory cells MC may share one vertical conductive line BL.

The semiconductor device 100 may include a first region R1 and a second region R2. The first region R1 may be a region in which the first array AR1, the second array AR2, and the third array AR3 are formed. The second region R2 may be a region in which the edge portions WLE of the stack structures WLS are disposed. The edge portions WLE of the stack structures WLS may include a plurality of steps ST. The first region R1 may be referred to as a cell array region in which the memory cells MC are disposed, and the second region R2 may be referred to as a contact region in which contact plugs WC are disposed. The contact plugs WC may be coupled to the edge portions WLE of the stack structures WLS, The contact plugs WC may be coupled to the edges of the horizontal conductive lines WL.

The memory cell MC may be disposed at a higher level than the lower structure LS. The memory cell MC may include a vertical conductive line BL, a horizontal conductive line WL, a horizontal layer HL, and a data storage element CAP. The vertical conductive line BL may be vertically oriented in the first direction D1, and the horizontal layer HL may be oriented horizontally along the second direction D2, The horizontal conductive line WL may be oriented horizontally in the third direction D3, The vertical conductive line BL may be coupled to first side of the horizontal layer HL, and the data storage element CAP may be coupled to second side opposite to said first side of the horizontal layer HL. The vertical conductive line BL may include a bit line, and the horizontal conductive line WL may include a word line. The data storage element CAP may include a memory element, such as a capacitor.

The horizontal layer HL and the horizontal conductive line WL may form a switching element TR, such as a transistor. The switching element TR may also be referred to as an access element or a selection element.

The memory cell MC may have a 1T-1C (1 Transistor-1 Capacitor) structure.

Referring to FIGS. 2B and 3A, the switching element TR may include a horizontal layer HL, a gate dielectric layer GD, and a horizontal conductive line WL. The horizontal conductive line WL may have a pair of parallel conductive lines, that is, the horizontal conductive line may have a double conductive line structure. For example, the horizontal conductive line WL may include first and second horizontal lines G1 and G2 that are facing each other with the horizontal layer HL interposed therebetween. The data storage element CAP may include a first electrode SN, a dielectric layer DE, and a second electrode PN.

The vertical conductive line BL may extend in a first direction D1 which is perpendicular to the surface of the lower structure LS. The horizontal layer HL may extend horizontally from the vertical conductive line BL in the second direction D2. The horizontal conductive line WL may extend horizontally in a third direction D3 crossing the first and second directions D1 and D2. The second electrode PN of the data storage element CAP may be coupled to a common plate PL.

The vertical conductive line BL may be vertically oriented in the first direction D1. The vertical conductive line BL may be referred to as a vertically oriented bit line or a pillar-type bit line. The vertical conductive line BL may include a conductive material. The vertical conductive line BL may include a silicon-based material, a metal-based material, or a combination thereof. The vertical conductive line BL may include polysilicon, a metal, a metal nitride, a metal silicide, or a combination thereof. The vertical conductive line BL may include polysilicon, titanium nitride, tungsten, or a combination thereof. For example, the vertical conductive line BL may include polysilicon or titanium nitride (TiN) which is doped with an N-type impurity. The vertical conductive line BL may include a stack (TiN/W) of titanium nitride and tungsten.

The horizontal conductive line WL may extend in the third direction D3 and may include a pair of a first horizontal line G1 and a second horizontal line G2. The first horizontal line G1 and the second horizontal line G2 may face each other with the horizontal layer HL interposed therebetween. A gate dielectric layer GD may be formed on an upper surface and a lower surface of the horizontal layer HL, respectively.

The horizontal layer HL may be spaced apart from the lower structure LS and extend in the second direction D2 which is parallel to the top surface of the lower structure LS. The horizontal layer HL may include a semiconductor material. For example, the horizontal layer HL may include polysilicon, monocrystalline silicon, germanium, or silicon-germanium. Referring to FIGS. 4A to 4E, the horizontal layer HL may include a first doped region SR, a second doped region DR, and a channel CH between the first doped region SR and the second doped region DR. The first doped region SR may be coupled to the vertical conductive line BL as illustrated in FIGS. 2B and 3A, The second doped region DR may be coupled to the data storage element CAP as illustrated in FIGS. 2B and 3A, and more specifically to the first electrode SN of the data storage element CAP. According to another embodiment of the present invention, the horizontal layer HL may include an oxide semiconductor material. For example, the oxide semiconductor material may include Indium Gallium Zinc Oxide (IGZO). When the horizontal layer HL is an oxide semiconductor material, the channel CH may be formed of an oxide semiconductor material, and the first and second doped regions SR and DR may be omitted. The horizontal layer HL may also be referred to as an active layer or a thin-body layer.

The first doped region SR and the second doped region DR may be doped with impurities of the same conductivity type. The first doped region SR and the second doped region DR may be doped with an N-type impurity or a P-type impurity. The first doped region SR and the second doped region DR may include at least one impurity selected among arsenic (As), phosphorus (P), boron (B), indium (In), and combinations thereof. The first doped region SR may be coupled to the vertical conductive line BL. The second doped region DR may be coupled to the first electrode SN of the data storage element CAP.

In the horizontal conductive line WL, the first horizontal line G1 and the second horizontal line G2 may have the same electric potential. For example, the first horizontal line G1 and the second horizontal line G2 may form a pair and may be coupled to one memory cell MC. The same driving voltage may be applied to the first horizontal line G1 and the second horizontal line G2, As such, the memory cell MC according to the embodiment of the present invention may have a double horizontal conductive line in which two first and second horizontal lines G1 and G2 are disposed adjacent to one channel CH. The first horizontal line G1 and the second horizontal line G2 may be electrically connected to each other through a pad WLP.

The horizontal layer HL may have a smaller thickness than the first and second horizontal lines G1 and G2. In other words, the vertical thickness of the horizontal layer HL in the first direction D1 may be smaller than the vertical thickness of each of the first and second horizontal lines G1 and G2 in the first direction D1.

The thin horizontal layer HL described above may be referred to as a thin-body layer. The thin horizontal layer HL may include a thin channel CH. The thin channel CH may be referred to as a ‘thin-body channel CH’. According to another embodiment of the present invention, the channel CH may have the same thickness as the first and second horizontal lines G1 and G2.

The upper and the lower surfaces of the horizontal layer HL may have a flat surface. In other words, the upper and the lower surfaces of the horizontal layer HL may be parallel to each other in the second direction D2.

A gate dielectric layer GD may be disposed between the first horizontal line G1 and the horizontal layer HL. A gate dielectric layer GD may be disposed between the second horizontal line G2 and the horizontal layer HL. The gate dielectric layer GD may include silicon oxide, silicon nitride, a high-k material, a ferroelectric material, an anti-ferroelectric material, or a combination thereof.

The horizontal conductive line WL may include a metal, a metal alloy, or a semiconductor material. For example, the first and second horizontal lines G1 and G2 of the horizontal conductive line WL may include a metal-based liner and a metal-based bulk. The metal-based liner may include a molybdenum-based material. The molybdenum-based material may include molybdenum or molybdenum nitride. According to the embodiment of the present invention, each of the first and second horizontal lines G1 and G2 may include molybdenum nitride.

The data storage element CAP may be horizontally disposed in the second direction D2 from the switching element TR. The data storage element CAP may include a first electrode SN extending horizontally from the horizontal layer HL in the second direction D2, The data storage element CAP may further include a second electrode PN over the first electrode SN and a dielectric layer DE between the first electrode SN and the second electrode PN. The first electrode SN, the dielectric layer DE, and the second electrode PN may be horizontally arranged in the second direction D2, The first electrode SN may have a horizontally oriented cylinder-shape. The dielectric layer DE may conformally cover the cylindrical inner wall and the cylindrical outer wall of the first electrode SN, The second electrode PN may cover the cylindrical inner wall and the cylindrical outer wall of the first electrode SN over the dielectric layer DE. The second electrode PN may be coupled to the common plate PL. The first electrode SN may be electrically connected to the second doped region DR.

The first electrode SN may have a three-dimensional structure, and the first electrode SN of the three-dimensional structure may have a horizontal three-dimensional structure which is oriented in the second direction D2. As an example of the three-dimensional structure, the first electrode SN may have a cylindrical shape. According to another embodiment of the present invention, the first electrode SN may have a pillar shape or a pylinder shape. The pylinder shape may refer to a structure in which a pillar shape and a cylinder shape are merged.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, and/or a tungsten nitride/tungsten (WN/W) stack. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the first electrode SN, and titanium nitride (TiN) may serve as a second electrode PN of a data storage element CAP, and tungsten nitride may be a low-resistance material.

The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including at least zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present invention, the dielectric layer DE may include a laminated structure in which a high-k material and a high-bandgap material are alternately stacked. For example, it may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a stack structure, a laminated structure, or a mixed structure including zirconium oxide, hafnium oxide, and aluminum oxide.

According to another embodiment of the present invention, the dielectric layer DE may include a ferroelectric material or an antiferroelectric material.

According to another embodiment of the present invention, an interface control layer for improving leakage current may be further formed between the first electrode SN and the dielectric layer DE. The interface control layer may include titanium oxide (TiO₂). The interface control layer may also be formed between the second electrode PN and the dielectric layer DE.

The data storage element CAP may include a metal-insulator-metal (MIM) capacitor. The first electrode SN and the second electrode PN may include a metal-based material.

The data storage element CAP may be replaced with another data storage material. For example, the data storage material may be a phase change material, a magnetic tunnel junction (MTJ), or a variable resistance material.

Diverse embodiments of the first and second horizontal lines G1 and G2 of the horizontal conductive line WL will be described with reference to FIGS. 4A to 4E.

Referring to FIGS. 4A to 4E, each of the first horizontal line G1 and the second horizontal line G2 may include a liner electrode GL and a bulk electrode GB. The liner electrode GL may be thinner than the bulk electrode GB. Since the resistance of the liner electrode GL decreases as it becomes thinner, the liner electrode GL may have a thickness of approximately 10 Å or less (1 to 10 Å), The liner electrode GL and the bulk electrode GB may be formed of different materials. The liner electrode GL may be formed of a molybdenum-based material. The bulk electrode GB may include a molybdenum-based material or a tungsten-based material. The liner electrode GL may be formed of a material having a higher work function than titanium nitride. For example, the liner electrode GL may be formed of molybdenum nitride (MoN). The bulk electrode GB may include molybdenum or tungsten. The stack of the liner electrode GL and the bulk electrode GB may include a molybdenum nitride/tungsten (MoN/W) stack or a molybdenum nitride/molybdenum (MoN/Mo) stack. Molybdenum nitride may have a work function of approximately 4.47 eV. Titanium nitride may have a work function of approximately 4.2 eV. Molybdenum nitride may have a higher work function than titanium nitride. To have a look at the shift amount of a flat band voltage, the molybdenum nitride/tungsten (MoN/W) stack may shift approximately 144 mV, and the molybdenum nitride/molybdenum (MoN/Mo) stack may shift approximately 270 mV. The molybdenum nitride/molybdenum (MoN/Mo) stack has a larger shift amount of the flat band voltage than the molybdenum nitride/tungsten (MoN/W) stack.

As a comparative example, the stack of the liner electrode GL and the bulk electrode GB may include a titanium nitride/tungsten (TiN/W) stack, but the flat band voltage shift amount of the titanium nitride/tungsten (TiN/W) stack may be approximately 52 mV, which is smaller than the flat band voltage shift amount of the molybdenum nitride/tungsten (MoN/W) stack. It may be seen from this that as the first and second horizontal lines G1 and G2 are formed of molybdenum nitride which has a greater work function than titanium nitride, the cell threshold voltage may be increased. Also, since the liner electrode GL overlaps with the channel CH, the cell threshold voltage of the channel CH increases, thereby controlling off-leakage. When the cell threshold voltage is increased, there is a margin so as to increase the thickness of the channel CH and thereby improve the process margin.

Each of the first horizontal line G1 and the second horizontal line G2 may be free of titanium nitride (TiN-free). Each of the first horizontal line G1 and the second horizontal line G2 may include a material having a greater work function than titanium nitride.

Referring to FIG. 4B, each of the first horizontal line G1 and the second horizontal line G2 may include a liner electrode GL, a bulk electrode GB, and a capping electrode GS, A combination of the capping electrode GS and the liner electrode GL may fully surround the bulk electrode GB. The capping electrode GS may be adjacent to the first doped region SR of the horizontal layer HL. The liner electrode GL and the capping electrode GS may be formed of the same material. For example, the liner electrode GL and the capping electrode GS may be formed of molybdenum nitride (MoN). The bulk electrode GB may include molybdenum or tungsten.

Referring to FIG. 4C, each of the first horizontal line G1 and the second horizontal line G2 may include a liner electrode GL, a bulk electrode GB, and a low work function electrode LG. The low work function electrode LG may be disposed on one side of the liner electrode GL, The low work function electrode LG may be adjacent to the second doped region DR of the horizontal layer HL. The low work function electrode LG and the liner electrode GL may be formed of different materials, and the low work function electrode LG and the bulk electrode GB may be formed of different materials. The liner electrode GL may be formed of molybdenum nitride (MoN). The bulk electrode GB may include molybdenum or tungsten. The low work function electrode LG may have a work function value which is lower than those of the liner electrode GL and the bulk electrode GB. The liner electrode GL and the bulk electrode GB may be referred to as high work function electrodes. The high work function electrode may include a high work function material. The high work function electrode may be a material having a higher work function than the mid-gap work function of silicon. For example, the high work function electrode may have a work function which is higher than approximately 4.4 eV.

The low work function electrode LG may include a low work function material. The low work function electrode LG may be a material having a lower work function than the mid-gap work function of silicon. For example, the low work function electrode LG may have a work function which is lower than approximately 4.4 eV. The low work function electrode LG may include doped polysilicon, and the doped polys con may be doped with an N-type impurity.

Referring to FIG. 4D, each of the first horizontal line G1 and the second horizontal line G2 may include the liner electrode GL, the bulk electrode GB, the capping electrode GS, and the low work function electrode LG, A combination of the capping electrode GS and the liner electrode GL may fully surround the bulk electrode GB. The capping electrode GS may be adjacent to the first doped region SR of the horizontal layer HL. The liner electrode GL and the capping electrode GS may be formed of the same material. The low work function electrode LG may be disposed on one side of the liner electrode GL, The low work function electrode LG may be adjacent to the second doped region DR of the horizontal layer HL. The low work function electrode LG and the liner electrode GL may be formed of different materials, and the low work function electrode LG and the bulk electrode GB may be formed of different materials. The liner electrode GL and the capping electrode GS may be formed of molybdenum nitride (MoN). The bulk electrode GB may include molybdenum or tungsten. The low work function electrode LG may have a lower work function value than the liner electrode GL and the bulk electrode GB. The low work function electrode LG may include a low work function material. The low work function electrode LG may be a material having a lower work function than the mid-gap work function of silicon. In other words, the low work function electrode LG may have a work function which is lower than approximately 4.4 eV, The low work function electrode LG may include doped polysilicon, and the doped polysilicon may be doped with an N-type impurity.

Referring to FIG. 4E, each of the first horizontal line G1 and the second horizontal line G2 may include a liner electrode GL, a bulk electrode GB, a capping electrode GS, a low work function electrode LG, and an additional low work function electrode LG′. In FIG. 4E, the low work function electrode LG may be referred to as a first low work function electrode, and the additional low work function electrode LG′ may be referred to as a second low work function electrode, A combination of the capping electrode GS and the liner electrode GL may fully surround the bulk electrode GB. The capping electrode GS may be adjacent to the first doped region SR of the horizontal layer HL. The liner electrode GL and the capping electrode GS may be formed of the same material. The low work function electrode LG may be disposed on one side of the liner electrode GL, and the additional low work function electrode LG′ may be disposed on one side of the capping electrode GS. The low work function electrode LG may be adjacent to the second doped region DR of the horizontal layer HL. The additional low work function electrode LG′ may be adjacent to the first doped region SR of the horizontal layer HL, The low work function electrode LG and the liner electrode GL may be formed of different materials, and the low work function electrode LG and the bulk electrode GB may be formed of different materials. The low work function electrode LG and the additional low work function electrode LG′ may be formed of the same material. The liner electrode GL and the capping electrode GS may be formed of molybdenum nitride (MoN). The bulk electrode GB may include molybdenum or tungsten. The low work function electrode LG and the additional low work function electrode LG′ may have a work function value which is lower than those of the liner electrode GL and the bulk electrode GB. The low work function electrode LG and the additional low work function electrode LG′ may include a low work function material. The low work function electrode LG and the additional low work function electrode LG′ may be formed of materials having a work function which is lower than the mid-gap work function of silicon. The low work function electrode LG and the additional low work function electrode LG′ may include doped polysilicon, and the doped polysilicon may be doped with an N-type impurity.

Referring to FIGS. 4C to 4E, the width of the low work function electrode LG in the second direction D2 may be smaller than the widths of the liner electrode GL and the bulk electrode GB. In FIG. 4E, the width of the low work function electrode LG and the width of the additional low work function electrode LG′ in the second direction D2 may be smaller than the widths of the liner electrode GL and the bulk electrode GB, Due to the difference in the widths, the volumes of the liner electrode GL and the bulk electrode GB may be greater than the volumes of the low work function electrode LG and the additional low work function electrode LG′, and thus the first and the second horizontal lines G1 and G2 may have a low resistance. The liner electrode GL, the bulk electrode GB, and the channel CH may vertically overlap with each other in the first direction D1. Referring to FIGS. 4C to 4E, each of the first and second horizontal lines G1 and G2 may have a dual work function electrode structure including a low work function material and a high work function material. The low work function electrode LG may be adjacent to the data storage element CAP, as illustrated in FIG. 2, and due to the low work function of the low work function electrode LG, a low electric field may be formed between the horizontal conductive line WL and the data storage dement CAP so as to improve the leakage current.

Referring to FIGS. 4A to 4E, each of the first and second horizontal lines G1 and G2 of the horizontal conductive line WL may include a molybdenum-based material. Accordingly, not only the threshold voltage of the switching element TR may be adjusted due to the high work function of the first and second horizontal lines G1 and G2, but also the height of the memory cell MC may be lowered by forming a low electric field. Therefore, at is also advantageous in terms of integration.

Referring to FIGS. 4A to 4E, the liner electrode GL and the bulk electrode GB may be formed by Atomic Layer Deposition (ALD), For example, when the liner electrode GL and the bulk electrode GB include molybdenum nitride and molybdenum, respectively, the molybdenum nitride and molybdenum may be formed by atomic layer deposition (ALD). The atomic layer deposition of molybdenum nitride may include repeating a sequential unit cycle of introducing a reaction gas, purging, introducing a molybdenum source material, and purging several times. The molybdenum source material may include MoO₂Cl₂ and the reactant gas may include a combination of NH₃ and H₂. The atomic layer deposition (ALD) of molybdenum may include repeating a sequential unit cycle of introducing a reaction gas, purging, introducing a molybdenum source material, and purging several times. The molybdenum source material may include MoO₂Cl₂ and the reactant gas may include H₂. Molybdenum nitride is required for uniform deposition of molybdenum.

According to another embodiment of the present invention, to form a molybdenum nitride/molybdenum stack, after an atomic layer of molybdenum nitride is deposited, it may be exposed to an annealing process performed in the atmosphere of hydrogen to reduce a portion of the molybdenum nitride into molybdenum.

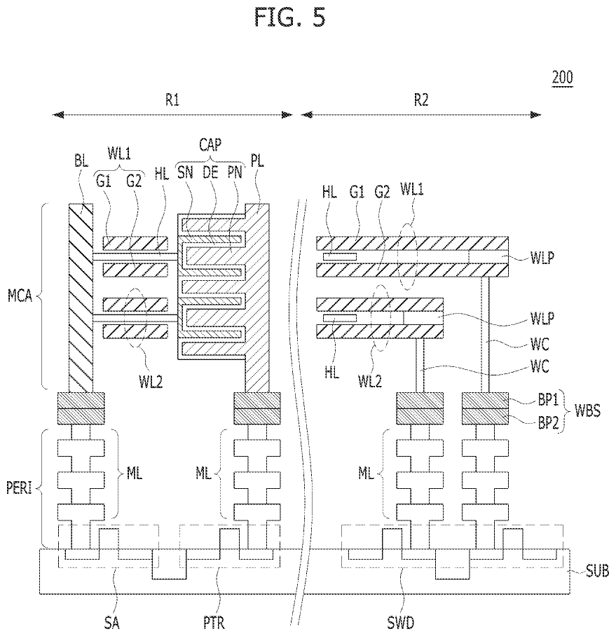

FIG. 5 is a simplified schematic cross-sectional view illustrating a semiconductor device 200 in accordance with another embodiment of the present invention. In FIG. 5, detailed descriptions on the constituent elements also appearing in FIGS. 1 to 4E will be omitted.

Referring to FIG. 5, the semiconductor device 200 may include a peripheral circuit portion PERI and a memory cell array MCA. The memory cell array MCA may be disposed over the peripheral circuit portion PERI. The memory cell array MCA and the peripheral circuit portion PERI may be coupled by wafer bonding. The semiconductor device 200 may have a COP (Cell-Over-Peripheral) structure.

The memory cell array MCA may include a plurality of memory cells. The memory cell array MCA may include a cell array region R1 and a contact region R2. The memory cell array MCA may include a vertical conductive line BL, a plurality of horizontal conductive lines WL1 and WL2, and a plurality of data storage elements CAP. Each of the horizontal conductive lines WL1 and WL2 may have a double horizontal line structure including a first horizontal line G1 and a second horizontal line G2. A horizontal layer HL may be disposed between the first horizontal line G1 and the second horizontal line G2, Each data storage element CAP may include a first electrode SN, a dielectric layer DE, and a second electrode PN. The second electrodes PN of the data storage elements CAP that are stacked vertically may be commonly coupled to a common plate PL.

The horizontal conductive lines WL1 and WL2 may extend from the cell array region R1 to the contact region R2, and the edge portions of the horizontal conductive lines WL1 and WL2 may be disposed in the contact region R2.

The edge portions of the horizontal conductive lines WL1 and WL2 may have a stepped structure. According to the embodiment of the present invention, the edge portions of the horizontal conductive lines WL1 and WL2 may have a reverse-stepped structure. The edge portions of the horizontal conductive lines WL1 and WL2 may further include pads WLP. Each of the pads WLP may be disposed between an edge portion of the first horizontal line G1 and an edge portion of the second horizontal line G2. The first horizontal line G1 and the second horizontal line G2 may be electrically connected to each other by the pads WLP. The edge portions of the horizontal conductive lines WL1 and WL2 may be respectively coupled to the contact plugs WC.

A bonding structure WBS may be disposed between the peripheral circuit portion PERT and the memory cell array MCA. The bonding structure WBS may include first bonding pads BP1 and second bonding pads BP2. The memory cell array MCA and the peripheral circuit portion PERT may be coupled to each other through metal-to-metal bonding. The memory cell array MCA and the peripheral circuit portion PERT may be coupled to each other through hybrid bonding. For example, they may be coupled to each other through the first bonding pads BP1 and the second bonding pads BP2. The metal-to-metal bonding may refer to direct bonding between the first bonding pads BP1 and the second bonding pads BP2. The hybrid bonding may refer to a combination of a metal-to-metal bonding and an insulating bonding. The first and second bonding pads BP1 and BP2 may include a metal material.

The vertical conductive line BL and the common plate PL may be respectively coupled to the first bonding pads BP1. The edge portions of the horizontal conductive lines WL1 and WL2 may be respectively coupled to the first bonding pads BP1 through the contact plugs WC.

The peripheral circuit portion PERI may include a plurality of control circuits and a plurality of interconnections ML formed over a substrate SUB. For example, the peripheral circuit portion PERI may include a sense amplifier SA, a sub-word line driver SWD, and a plate control circuit PTR. The sense amplifier SA may be coupled to the vertical conductive line BL through the interconnections ML, The sub-word line driver SWD may be coupled to the horizontal conductive lines WL1 and WL2 through the interconnection ML. A common plate control circuit PTR may be coupled to the common plate PL through the interconnection ML.

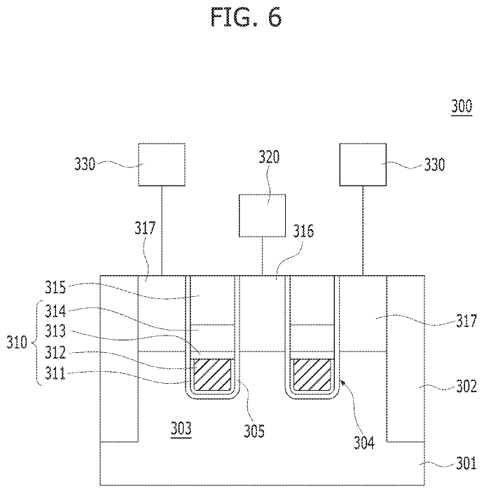

FIG. 6 is a simplified schematic cross-sectional view illustrating a semiconductor device 300 in accordance with another embodiment of the present invention.

Referring to FIG. 6, the semiconductor device 300 may include a buried word line structure 310, a bit line 320, and a capacitor 330, An isolation layer 302, an active region 303, and a gate trench 304 may be formed in the substrate 301, A gate dielectric layer 305 may be formed on a surface of the gate trench 304. A first source/drain region 316 and a second source/drain region 317 may be formed in the active region 303. The first source/drain region 316 and the second source/drain region 317 may be spaced apart from each other by a gate trench 304. The buried word line structure 310 may partially fill the gate trench 304 over the gate dielectric layer 305. A word line capping layer 315 may be formed over the buried word line structure 310. The bit line 320 may be coupled to the first source/drain region 316, and the capacitor 330 may be coupled to the second source/drain region 317.

The buried word line structure 310 may include a liner electrode 311, a bulk electrode 312, a capping electrode 313, and a low work function electrode 314, The liner electrode 311 may be thinner than the bulk electrode 312. Since the resistance of the liner electrode 311 decreases as it becomes thinner, the liner electrode 311 may have a thickness of approximately 10 Å or less (1 to 10 Å). The liner electrode 311 and the bulk electrode 312 may be formed of different materials. The liner electrode 311 may be a molybdenum-based material. The bulk electrode 312 may include a molybdenum-based material or a tungsten-based material. The liner electrode 311 may be formed of molybdenum nitride (MoN). The bulk electrode 312 may include molybdenum or tungsten. The stack of the liner electrode 311 and the bulk electrode 312 may include a molybdenum nitride/tungsten (MoN/W) stack or a molybdenum nitride/molybdenum (MoN/Mo) stack. The buried word line structure 310 may be free of titanium nitride (TiN-free). The buried word line structure 310 may include a material having a greater work function than titanium nitride.

A combination of the capping electrode 313 and the liner electrode 311 may fully surround the bulk electrode 312. The liner electrode 311 and the capping electrode 313 may be formed of the same material. The liner electrode 311 and the capping electrode 313 may be formed of molybdenum nitride (MoN).

The low work function electrode 314 may horizontally overlap with the first and second source/drain regions 316 and 317. The low work function electrode 314 and the capping electrode 313 may be formed of different materials, and the low work function electrode 314 and the bulk electrode 312 may be formed of different materials. The low work function electrode 314 and the liner electrode 311 may be formed of different materials. The low work function electrode 314 may have a lower work function value than the liner electrode 311 and the bulk electrode 312. The liner electrode 311 and the bulk electrode 312 may be referred to as high work function electrodes.

The low work function electrode 314 may include a low work function material. The low work function electrode 314 may include doped polysilicon, and the doped polysilicon may be doped with an N-type impurity.

A gate-induced drain leakage GIDL may be suppressed by the low work function electrode 314.

According to the embodiment of the present invention, since the cell threshold voltage is raised without increasing the leakage current, off-leakage may be controlled.

According to the embodiment of the present invention, the floating body effect may be suppressed by applying a low work function electrode and thus releasing an e-field.

While the present invention has been described with respect to specific embodiments, it will be apparent to those skilled in the art that various changes and modifications may be made without departing from the spirit and scope of the invention as defined in the following claims.

What is claimed is:

1. A semiconductor device, comprising:
a vertical conductive line oriented vertically in a first direction;
a horizontal layer oriented horizontally in a second direction from the vertical conductive line; and
a horizontal conductive line oriented horizontally in a third direction intersecting with the horizontal layer,
wherein the horizontal conductive line includes:
a high work function electrode including a material having a higher work function than titanium nitride; and
a low work function electrode including a semiconductor material.

2. The semiconductor device of claim 1, wherein the low work function electrode has a lower work function than the high work function electrode.

3. The semiconductor device of claim 1, wherein the high work function electrode includes a molybdenum-based material.

4. The semiconductor device of claim 1, wherein the high work function electrode includes:
a first molybdenum-based electrode; and
a second molybdenum-based electrode disposed between the first molybdenum-based electrode and the horizontal layer, and
the first molybdenum-based electrode and the second molybdenum-based electrode are different.

5. The semiconductor device of claim 1, wherein the high work function electrode includes:
a molybdenum bulk electrode; and
a molybdenum nitride liner electrode disposed between the molybdenum bulk electrode and the horizontal layer.

6. The semiconductor device of claim 5, wherein the molybdenum nitride liner electrode partially surrounds the molybdenum bulk electrode.

7. The semiconductor device of claim 1, wherein the low work function electrode includes doped polysilicon.

8. The semiconductor device of claim 1, wherein the high work function electrode and the low work function electrode are disposed horizontally in the third direction.

9. The semiconductor device of claim 1, wherein the horizontal conductive line further includes
a capping electrode in contact with the high work function electrode.

10. The semiconductor device of claim 9, wherein the capping electrode includes molybdenum nitride.

11. The semiconductor device of claim 1, further comprising:
a vertical conductive line coupled to a first-side end of the horizontal layer; and
a data storage element coupled to a second-side end of the horizontal layer.

12. A semiconductor device, comprising:
a vertical conductive line oriented vertically in a first direction;
a horizontal layer oriented horizontally in a second direction from the vertical conductive line; and
a horizontal conductive line oriented horizontally in a third direction intersecting with the horizontal layer,
wherein the horizontal conductive line includes:
a high work function electrode including a molybdenum-based material;
a first low work function electrode disposed on a first side of the high work function electrode; and
a second low work function electrode disposed on a second side of the high work function electrode.

13. The semiconductor device of claim 12, wherein the first and second low work function electrodes have a lower work function than the high work function electrode.

14. The semiconductor device of claim 12, wherein the high work function electrode includes:
a first molybdenum-based electrode; and
a second molybdenum-based electrode disposed between the first molybdenum-based electrode and the horizontal layer,
wherein the first molybdenum-based electrode and the second molybdenum-based electrode are different.

15. The semiconductor device of claim 12, wherein the high work function electrode includes:
a molybdenum bulk electrode; and
a molybdenum nitride liner electrode disposed between the molybdenum bulk electrode and the horizontal layer.

16. The semiconductor device of claim 15, wherein the molybdenum nitride liner electrode partially surrounds the molybdenum bulk electrode.

17. The semiconductor device of claim 12, wherein the first and second low work function electrodes include doped polysilicon.

18. The semiconductor device of claim 12, wherein the first low work function electrode, the high work function electrode, and the second low work function electrode are disposed horizontally in the third direction.

19. The semiconductor device of claim 12, wherein the horizontal conductive line further includes
a capping electrode in contact with the high work function electrode.

20. The semiconductor device of claim 19, wherein the capping electrode includes molybdenum nitride.

21. The semiconductor device of claim 12, wherein the first and second low work function electrodes include doped polysilicon.

22. The semiconductor device of claim 12, wherein the horizontal layer includes
a first doped region,
a second doped region, and
a channel between the first doped region and the second doped region.

23. The semiconductor device of claim 22, wherein the channel and the high work function electrode vertically overlap with each other, and
the first work function electrode vertically overlaps with the first doped region, and
the second work function electrode vertically overlaps with the second doped region.

24. The semiconductor device of claim 22, further comprising:
a vertical conductive line coupled to the first doped region; and
a data storage element coupled to the second doped region.
